(19) United States
(12) Patent Application Publication
(10) Pub. No.: US 2026/0107493 A1
(43) Pub. Date: Apr. 16, 2026

(54) NITRIDE SEMICONDUCTOR DEVICE

(71) Applicant: ROHM CO., LTD., Kyoto-shi (JP)

(72) Inventors: Shinya TAKADO, Kyoto (JP); Hirotaka OTAKE, Kyoto (JP); Kazuya NAGASE, Kyoto (JP)

(73) Assignee: ROHM CO., LTD., Kyoto-shi (JP)

(21) Appl. No.: 19/178,913

(22) Filed: Apr. 15, 2025

Related U.S. Application Data
(63) Continuation of application No. PCT/JP2023/034856, filed on Sep. 26, 2023.

(30) Foreign Application Priority Data
Oct. 17, 2022 (JP) 2022-166304

(51) Int. Cl. H10D 30/47; H10D 62/10; H10D 62/815; H10D 64/00

(52) U.S. Cl. CPC H10D 30/475; H10D 62/103; H10D 62/8171; H10D 64/111

(57) ABSTRACT

A nitride semiconductor device includes a first nitride semiconductor layer, a second nitride semiconductor layer formed on the first nitride semiconductor layer and having a larger bandgap than the first nitride semiconductor layer, and a gate electrode, a source electrode, and a drain electrode formed above the second nitride semiconductor layer. The first nitride semiconductor layer is a layer including GaN. An X-ray rocking curve for a surface of the first nitride semiconductor layer has a half width that is 1100 arcseconds greater and 1400 arcseconds or less.

### CROSS-REFERENCE TO RELATED APPLICATIONS

This application is a continuation of and claims the benefit of priority from, International Application No. PCT/JP2023/034856, filed on Sep. 26, 2023, which claims the benefit of priority from Japanese Patent Application No. 2022-166304, filed on Oct. 17, 2022, the entire contents of each of which are incorporated herein by reference.

### BACKGROUND

### 1. Field

The present disclosure relates to a nitride semiconductor device.

### 2. Description of Related Art

High-electron-mobility transistors (HEMTs) that use nitride semiconductors, such as gallium nitride (GaN), are now being commercialized. Japanese Laid-Open Patent Publication No. 2017-73506 describes one example of a normally-off HEMT using a nitride semiconductor device.

### BRIEF DESCRIPTION OF THE DRAWINGS

FIG. 1 is a schematic cross-sectional view of an exemplary nitride semiconductor device according to an embodiment.

FIG. 2 is a schematic cross-sectional view illustrating an exemplary structure of various nitride semiconductor layers formed on a semiconductor substrate in the nitride semiconductor device illustrated in FIG. 1.

FIG. 3 is a schematic diagram illustrating a (102) surface of a first nitride semiconductor layer.

FIG. 4 is a schematic diagram illustrating a screw dislocation.

FIG. 5 is a schematic diagram illustrating an edge dislocation.

FIG. 6 is a graph illustrating a relationship between an on-resistance variation rate and an XRC half width measured for various nitride semiconductor devices including a first nitride semiconductor layer having a different crystal defect density with respect to the (102) surface of the first nitride semiconductor layer.

Throughout the drawings and the detailed description, the same reference numerals refer to the same elements. The drawings may not be to scale, and the relative size, proportions, and depiction of elements in the drawings may be exaggerated for clarity, illustration, and convenience.

### DETAILED DESCRIPTION

This description provides a comprehensive understanding of the methods, apparatuses, and/or systems described. Modifications and equivalents of the methods, apparatuses, and/or systems described are apparent to one of ordinary skill in the art. Sequences of operations are exemplary, and may be changed as apparent to one of ordinary skill in the art, with the exception of operations necessarily occurring in a certain order. Descriptions of functions and constructions that are well known to one of ordinary skill in the art may be omitted.

Exemplary embodiments may have different forms, and are not limited to the examples described. However, the examples described are thorough and complete, and convey the full scope of the disclosure to one of ordinary skill in the art.

In this specification, “at least one of A and B” should be understood to mean “only A, only B, or both A and B.”

### 1. Overall Structure of Nitride Semiconductor Device

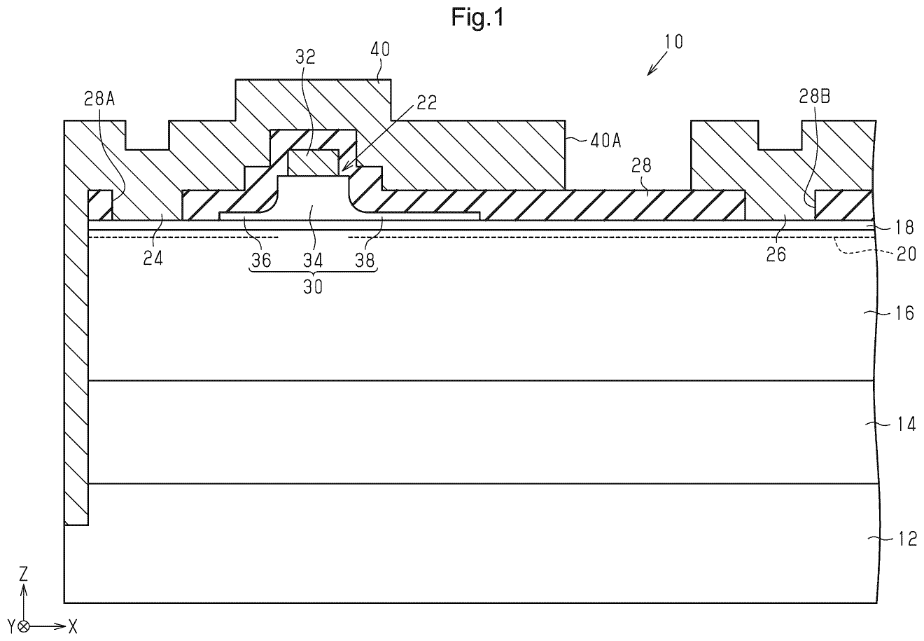

FIG. 1 is a schematic cross-sectional view illustrating an example of a nitride semiconductor device 10 according to an embodiment. The nitride semiconductor device 10 is, for example, a HEMT using GaN. The nitride semiconductor device 10 includes a semiconductor substrate 12, a buffer layer 14 formed on the semiconductor substrate 12, a first nitride semiconductor layer 16 formed on the buffer layer 14, and a second nitride semiconductor layer 18 formed on the first nitride semiconductor layer 16.

The semiconductor substrate 12 may be formed from silicon (Si), silicon carbide (SiC), GaN, sapphire, or other substrate materials. In an example, the semiconductor substrate 12 is a Si substrate. The semiconductor substrate 12 may have a thickness of, for example, 200 μm or greater and 1500 μm or less. Among XYZ-axes that are orthogonal to each other illustrated in FIG. 1, a Z-axis direction is orthogonal to a main surface (upper surface in FIG. 1) of the semiconductor substrate 12. Unless otherwise indicated, the term “plan view” as used in this specification will refer to a view of the nitride semiconductor device 10 taken from above in the Z-axis direction.

The buffer layer 14 includes one or more nitride semiconductor layers. For example, the buffer layer 14 may be formed from any material that limits warping of the semiconductor substrate 12 and formation of cracks in the nitride semiconductor device 10 caused by a difference in coefficient of thermal expansion between the semiconductor substrate 12 and the first nitride semiconductor layer 16.

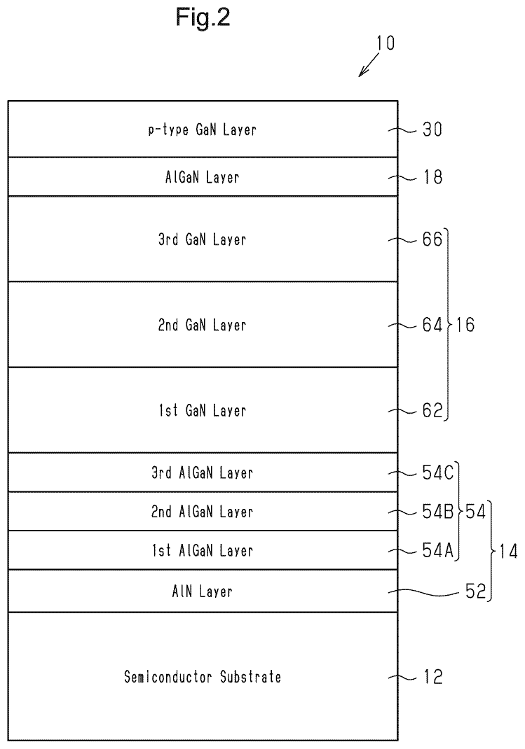

In some embodiments, the buffer layer 14 may include at least one of an aluminum nitride (AlN) layer, an aluminum gallium nitride (AlGaN) layer, and a graded AlGaN layer of different aluminum (Al) compositions. In an example, the buffer layer 14 may include a single AlN layer, a single AlGaN layer, a layer having an AlGaN/GaN superlattice structure, a layer having an AlN/AlGaN superlattice structure, or a layer having an AlN/GaN superlattice structure. An exemplary structure of the buffer layer 14 will be described later with reference to FIG. 2.

The first nitride semiconductor layer 16 is a layer including GaN. In some embodiments, the first nitride semiconductor layer 16 includes a GaN composite layer in which multiple GaN layers are stacked. The first nitride semiconductor layer 16 may have a thickness of, for example, 0.5 μm or greater and 2 μm or less. An exemplary structure of the first nitride semiconductor layer 16 will be described later with reference to FIG. 2.

The second nitride semiconductor layer 18 is composed of a nitride semiconductor having a larger band gap than the first nitride semiconductor layer 16. The second nitride semiconductor layer 18 may be, for example, an AlGaN layer. The band gap increases as the Al composition increases. Thus, the second nitride semiconductor layer 18, which is an AlGaN layer, has a larger band gap than the first nitride semiconductor layer 16, which includes the GaN composite layer. In an example, the second nitride semiconductor layer 18 is composed of AlₓGa₁₋ₓN, where 0.1<x<0.4. More preferably, 0.1<x<0.3. The second nitride semiconductorlayer 18 may have a thickness of, for example, 5 nm or greater and 20 nm or less.

The first nitride semiconductor layer 16 and the second nitride semiconductor layer 18 are composed of nitride semiconductors having different lattice constants. Thus, the nitride semiconductor (e.g., GaN) of the first nitride semiconductor layer 16 and the nitride semiconductor (e.g., AlGaN) of the second nitride semiconductor layer 18 form a lattice-mismatched heterojunction. The energy level of the conduction band of the first nitride semiconductor layer 16 in the vicinity of the heterojunction interface is lower than the Fermi level due to spontaneous polarization of the first nitride semiconductor layer 16 and the second nitride semiconductor layer 18 and piezoelectric polarization caused by crystal strain in the vicinity of the heterojunction interface. As a result, at a location close to the heterojunction interface between the first nitride semiconductor layer 16 and the second nitride semiconductor layer 18 (e.g., within range approximately a few nanometers from the interface), two-dimensional electron gas 20 (2DEG) spreads in the first nitride semiconductor layer 16.

The nitride semiconductor device 10 includes a gate structure 22, a source electrode 24, and a drain electrode 26 that are formed on the second nitride semiconductor layer 18, and a passivation layer 28 that is formed on the second nitride semiconductor layer 18 and covers the gate structure 22. The passivation layer 28 includes a source opening 28A and a drain opening 28B that partially expose the upper surface of the second nitride semiconductor layer 18. The passivation layer 28 may be composed of, for example, at least one of silicon nitride (SiN), silicon dioxide (SiO₂), silicon oxynitride (SiON), aluminum oxide (Al₂O₃), AlN, and aluminum oxynitride (AlON). The passivation layer 28 may have a thickness of, for example, 80 nm or greater and 150 nm or less.

As illustrated in FIG. 1, in some embodiments, the gate structure 22 includes a gate layer 30 and a gate electrode 32 formed on the gate layer 30. The gate layer 30 may be, for example, a GaN layer doped with an acceptor impurity, that is, a p-type GaN layer. In this case, the acceptor impurity may include, for example, at least one of zinc (Zn), magnesium (Mg), and carbon (C). For example, the maximum concentration of the acceptor impurity in the gate layer 30 may be 7×10¹⁸ cm⁻³ or greater and 1×10²⁰ cm⁻³ or less.

The gate layer 30 is arranged between the source opening 28A and the drain opening 28B of the passivation layer 28 in the X-axis direction illustrated in FIG. 1. The gate layer 30 is separated from the source opening 28A and the drain opening 28B and located closer to the source opening 28A than to the drain opening 28B.

The gate electrode 32 includes one or more metal layers. In some embodiments, the gate electrode 32 is formed of, for example, a titanium nitride (TiN) layer. In other embodiments, the gate electrode 32 may be formed of a first metal layer formed from titanium (Ti) and a second metal layer formed on the first metal layer and formed from TiN. The gate electrode 32 forms a Schottky junction with the gate layer 30. The gate electrode 32 may have a thickness of, for example, 50 nm or greater and 200 nm or less.

The source electrode 24 and the drain electrode 26 each include one or more metal layers. For example, the source electrode 24 and the drain electrode 26 may be formed from one or any combination of a Ti layer, a TiN layer, an Al layer, an AlSiCu layer, and an AlCu layer.

The source opening 28A is filled with at least part of the source electrode 24, which is in ohmic contact with the 2DEG 20 immediately under the second nitride semiconductor layer 18 through the source opening 28A. In the same manner, the drain opening 28B is filled with at least part of the drain electrode 26, which is in ohmic contact with the 2DEG 20 immediately under the second nitride semiconductor layer 18 through the drain opening 28B. In the example illustrated in FIG. 1, the semiconductor substrate 12 is connected to the source electrode 24, and voltage having the same potential as that at the source electrode 24 is applied to the semiconductor substrate 12.

### 2. Exemplary Gate Structure

As described above, in the example illustrated in FIG. 1, the gate structure 22 includes the gate layer 30 and the gate electrode 32. The gate layer 30 includes an upper surface on which the gate electrode 32 is located and a lower surface in contact with the second nitride semiconductor layer 18. In some embodiments, the gate layer 30 includes a gate layer main body 34, which includes the upper surface of the gate layer 30, and a source-side extension 36 and a drain-side extension 38, each having a smaller thickness than the gate layer main body 34. The gate layer main body 34, the source-side extension 36, and the drain-side extension 38 are each in contact with the second nitride semiconductor layer 18.

The source-side extension 36 extends from the gate layer main body 34 toward the source opening 28A. The passivation layer 28 is present between the source-side extension 36 and the source electrode 24, which is embedded in the source opening 28A. The drain-side extension 38 extends from the gate layer main body 34 toward the drain opening 28B. The passivation layer 28 is present between the drain-side extension 38 and the drain electrode 26, which is embedded in the drain opening 28B.

The gate layer main body 34 is located between the source-side extension 36 and the drain-side extension 38 and is formed integrally with the source-side extension 36 and the drain-side extension 38. In the example illustrated in FIG. 1, the gate layer main body 34 has a ridge-shaped cross section (rectangular cross section). However, the cross-sectional shape of the gate layer main body 34 is not particularly limited and may be, for example, a trapezoid or other cross-sectional shape. The source-side extension 36 and the drain-side extension 38 result in the lower surface of the gate layer 30 having a larger area than the upper surface of the gate layer 30.

As illustrated in FIG. 1, in some embodiments, the drain-side extension 38 extends outward from the gate layer main body 34 over a greater length than the source-side extension 36 in plan view. Thus, the drain-side extension 38 may have a greater dimension in the X-axis direction than the source-side extension 36. The X-axis direction dimension (length) of the source-side extension 36 may be, for example, 0.2 μm or greater and 0.3 μm or less. The X-axis direction dimension (length) of the drain-side extension 38 may be, for example, 0.2 μm or greater and 0.6 μm or less.

The gate layer main body 34 corresponds to a relatively thick portion of the gate layer 30. The thickness of the gate layer main body 34 may be, for example, 80 nm or greater and 150 nm or less. The thickness of the gate layer main body 34 may be determined in accordance with various parameters including the gate threshold voltage. The source-side extension 36 and the drain-side extension 38 each have a smaller thickness than the gate layer main body 34. In an example, the thickness of each of the source-side extension 36 and the drain-side extension 38 may be less than or equal to one half the thickness of the gate layer main body 34.

The source-side extension 36 and the drain-side extension 38 may each include a flat portion having a substantially constant thickness. The thickness of the flat portion of the source-side extension 36 and the thickness of the flat portion of the drain-side extension 38 may be, for example, 5 nm or greater and 25 nm or less. In this specification, “substantially constant thickness” refers to a thickness being within a manufacturing variation range (e.g., 20%). As illustrated in FIG. 1, in some embodiments, the source-side extension 36 and the drain-side extension 38 may each include an intermediate portion between the flat portion and the gate layer main body 34, and the intermediate portion may have a greater thickness than the flat portion. In an example, the thickness of the intermediate portion gradually decreases as the gate layer main body 34 becomes farther.

In the gate structure 22 illustrated in FIG. 1, the gate layer 30, which includes an acceptor impurity, is arranged immediately under the gate electrode 32. In this structure, when a gate input voltage applied to the gate electrode 32 results in the gate-source voltage exceeding a positive threshold voltage, the 2DEG 20 forms a channel (current passage) in a region of the first nitride semiconductor layer 16 immediately under the gate layer main body 34 to electrically connect the source and the drain. When the gate-source voltage does not exceed the threshold voltage, the 2DEG 20 disappears from at least part of the region of the first nitride semiconductor layer 16 immediately under the gate layer main body 34 (refer to FIG. 1). This is because the gate layer main body 34, which includes the acceptor impurity, increases the energy levels of the first nitride semiconductor layer 16 and the second nitride semiconductor layer 18, thereby depleting the 2DEG 20. Thus, the nitride semiconductor device 10 is a normally-off HEMT.

### 3. Exemplary Field Plate Electrode Structure

As illustrated in FIG. 1, in some embodiments, the nitride semiconductor device 10 includes a field plate electrode 40 formed on the passivation layer 28. In the example illustrated in FIG. 1, the field plate electrode 40 is formed integrally with the source electrode 24 and covers the entirety of the gate structure 22 in plan view. In this structure, the field plate electrode 40 may be considered as part of the source electrode 24. The field plate electrode 40 receives a voltage having the same potential as the source electrode 24. Alternatively, the field plate electrode 40 may be arranged separately from the source electrode 24, and a control voltage other than the source voltage may be applied to the field plate electrode 40.

The field plate electrode 40 is arranged separately from the drain electrode 26. The field plate electrode 40 includes an end 40A located between the gate layer 30 (drain-side extension 38) and the drain electrode 26 (drain opening 28B) in plan view. The field plate electrode 40 mitigates electric field concentration at the vicinity of the end of the gate electrode 32 and the vicinity of the end of the gate layer 30 when a drain voltage is applied to the drain electrode 26 in the zero bias state, in which no gate input voltage is applied to the gate electrode 32.

### 4. Exemplary Structure of Various Nitride Semiconductor Layers on Semiconductor Substrate

FIG. 2 is a schematic cross-sectional view illustrating an exemplary structure of various nitride semiconductor layers formed on the semiconductor substrate 12. As described above, the buffer layer 14, the first nitride semiconductor layer 16, the second nitride semiconductor layer 18, and the gate layer 30 (third nitride semiconductor layer) are formed in this order on the semiconductor substrate 12. An exemplary structure of each layer will be described below.

### 4-1. Buffer Layer

The exemplary structure of the buffer layer 14 will now be described. In some embodiments, the buffer layer 14 may include a first buffer layer 52 formed on the semiconductor substrate 12 and a second buffer layer 54 formed on the first buffer layer 52. The first buffer layer 52 may be, for example, an AlN layer. The first buffer layer 52 may have a thickness of, for example, 100 nm or greater and 300 nm or less.

The second buffer layer 54 may be, for example, an AlGaN composite layer in which multiple AlGaN layers are stacked. In some embodiments, the second buffer layer 54 may be a graded AlGaN layer in which multiple AlGaN layers having different aluminum (Al) compositions are stacked. In the example illustrated in FIG. 2, the second buffer layer 54 is formed as a graded AlGaN layer obtained by sequentially stacking three AlGaN layers, namely, a first AlGaN layer 54A, a second AlGaN layer 54B, and a third AlGaN layer 54C. The first to third AlGaN layers 54A, 54B, and 54C may each have a thickness of, for example, 100 nm or greater and 300 nm or less.

The third AlGaN layer 54C is located in the uppermost layer of the second buffer layer 54 (buffer layer 14). In some embodiments, the third AlGaN layer 54C may have a lower Al composition and a greater thickness than the second AlGaN layer 54B. The second AlGaN layer 54B may have a lower Al composition than the first AlGaN layer 54A and have the same thickness as the first AlGaN layer 54A. In an example, the thickness of each of the first and second AlGaN layers 54A and 54B may be approximately 100 nm. The thickness of the third AlGaN layer 54C may be twice or more than the thickness of the second AlGaN layer 54B and may be, for example, 200 nm or greater. The proportions of Al composition in the first to third AlGaN layers 54A, 54B, and 54C may be approximately 80% (±5%), approximately 50% (±5%), and approximately 20% (±5%), respectively.

The third AlGaN layer 54C, which differs in Al composition from the second AlGaN layer 54B (in the example illustrated in FIG. 2, has a lower Al composition than the second AlGaN layer 54B), grows in a strained manner with respect to the lattice constant of the second AlGaN layer 54B. The third AlGaN layer 54C has a greater thickness than the second AlGaN layer 54B. This promotes occurrence of lattice relief (dislocation) in the third AlGaN layer 54C to reduce the internal stress (strain caused by lattice mismatching) accumulated as strain in the third AlGaN layer 54C. As a result, the density of crystal defect is increased by the lattice relief. In this regard, in some embodiments, for example, the third AlGaN layer 54C has a lower Al composition and a greater thickness than the second AlGaN layer 54B to increase the density of crystal defect in the buffer layer 14 (thereby increasing the density of crystal defect in the first nitride semiconductor layer 16). Alternatively, the number of AlGaN layers forming the second buffer layer 54 and the thickness of each layer are adjusted to increase the density of crystal defect in the buffer layer 14.

The buffer layer 14 may include an impurity that forms an acceptor level. The impurity in the buffer layer 14 may be, for example, at least one of carbon (C) and iron (Fe). The concentration of the impurity may be, for example, 4×10¹⁶ cm⁻³ or greater. In some embodiments, such an impurity is introduced into part of the buffer layer 14 so that the buffer layer 14 becomes semi-insulative. This limits current leakage in the buffer layer 14, thereby improving the breakdown voltage. In an example, in the second buffer layer 54, the impurity may be introduced into only the third AlGaN layer 54C or only the second and third AlGaN layer 54B and 54C. Alternatively, the impurity may be introduced into all of the first to third AlGaN layers 54A, 54B, and 54C in the second buffer layer 54. Of the first to third AlGaN layers 54A to 54C, the layer doped with an impurity forming the acceptor level corresponds to an impurity-doped AlGaN layer.

### 4-2. First Nitride Semiconductor Layer

The exemplary structure of the first nitride semiconductor layer 16 will now be described. As described above, the first nitride semiconductor layer 16 may include a GaN composite layer in which multiple GaN layers are stacked. In some embodiments, the GaN composite layer may be formed by alternately stacking an impurity-doped GaN layer, which is doped with an impurity forming an acceptor level, and a non-doped GaN layer one or more times. The uppermost layer of the GaN composite layer is a non-doped GaN layer. The term “non-doped GaN layer” used in the present disclosure is defined as a GaN layer into which impurities are not introduced intentionally.

In the GaN composite layer, the impurity in the impurity-doped GaN layer may be, for example, carbon (C). The concentration of the impurity in the impurity-doped GaN layer may be 5×10¹⁷ cm⁻³ or greater and 5×10¹⁹ cm⁻³ or less. In some embodiments, such an impurity is introduced into part of the first nitride semiconductor layer 16 so that at least part of the first nitride semiconductor layer 16 excluding a peripheral layer region becomes semi-insulative. This limits leakage current in the first nitride semiconductor layer 16, thereby improving the breakdown voltage.

In the example illustrated in FIG. 2, the first nitride semiconductor layer 16 is formed as a GaN composite layer having a three-layer structure obtained by sequentially stacking three GaN layers, namely, a first GaN layer 62, a second GaN layer 64, and a third GaN layer 66. The first GaN layer 62 is a non-doped GaN layer. The second GaN layer 64 is an impurity-doped GaN layer. The third GaN layer 66 is a non-doped GaN layer. The 2DEG 20 (refer to FIG. 1), which is the channel of the HEMT, is formed in the third GaN layer 66 located at the uppermost layer in the GaN composite layer (first nitride semiconductor layer 16). The third GaN layer 66, in which the 2DEG 20 is formed, is also functionally referred to as an electron transit layer.

The first to third GaN layers 62, 64, and 66 may have the same thickness or different thicknesses. The thickness of the first GaN layer 62 may be, for example, 50 nm or greater and 300 nm or less. The thickness of the second GaN layer 64 may be, for example, 300 nm or greater and 600 nm or less. The thickness of the third GaN layer 66 may be, for example, 200 nm or greater and 500 nm or less. As described above, the thickness of the GaN composite layer, that is, the entire first nitride semiconductor layer 16, may be, for example, 0.5 μm or greater and 2 μm or less.

In some embodiments, the number of one or more impurity-doped GaN layers (in the example illustrated in FIG. 2, the second GaN layer 64) and the thickness of each layer and/or the number of one or more non-doped GaN layers (in the example illustrated in FIG. 2, the first GaN layer 62 and the third GaN layer 66) and the thickness of each layer are adjusted to increase the density of crystal defects in the first nitride semiconductor layer 16. The crystal defects are formed as dislocations (threading dislocations) linearly extending in the stacking direction over an impurity-doped GaN layer and a non-doped GaN layer. These dislocations have the tendency of binding to each other and decreasing during the process of propagating a non-doped GaN layer located on the impurity-doped GaN layer (or the impurity-doped AlGaN layer of the buffer layer 14). Therefore, for example, the thickness of the non-doped GaN layer formed on the impurity-doped GaN layer (or the impurity-doped AlGaN layer of the buffer layer 14) is decreased to limit the decreasing of the dislocations in the non-doped GaN layer, thereby maintaining the density of crystal defects in the first nitride semiconductor layer 16. The purpose of controlling the density of crystal defects in the first nitride semiconductor layer 16 will be described later.

### 4-3. Second Nitride Semiconductor Layer and Gate Layer (Third Nitride Semiconductor Layer)

In the example illustrated in FIG. 2, the second nitride semiconductor layer 18 is an AlGaN layer. The gate layer 30 is a p-type GaN layer. The second nitride semiconductor layer 18 may be functionally referred to as an electron supply layer in relation to the electron transit layer (third GaN layer 66) of the first nitride semiconductor layer 16. Since the p-type GaN layer is arranged as the gate layer 30, the nitride semiconductor device 10 is configured as a normally-off HEMT as described above.

### 5. Acceptor Compensation by Controlling Crystal Defect Density

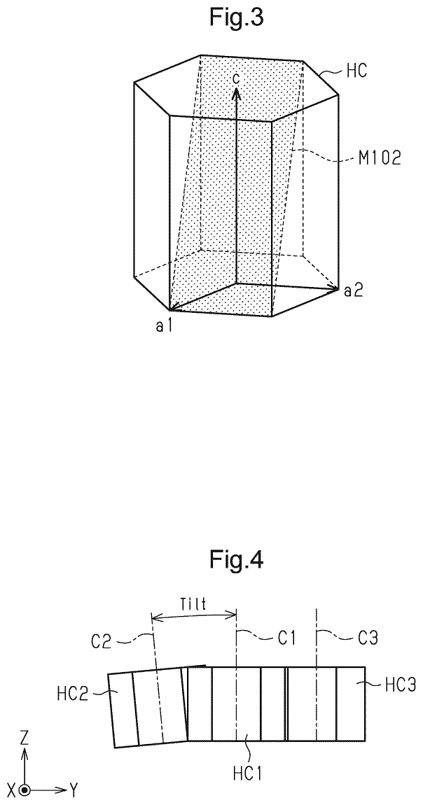

The acceptor compensation by controlling the crystal defect density will now be described with reference to FIGS. 3 to 6. In the nitride semiconductor device 10 configured as a HEMT, the on-resistance may be increased by electrons trapped at the deep acceptor level in the crystals of the first nitride semiconductor layer 16 or the buffer layer 14.

More specifically, electrons that are trapped at the acceptor level in the crystal decrease the carrier (electron) concentration of the 2DEG 20 generated in the first nitride semiconductor layer 16 (in the example illustrated in FIG. 2, the electron transit layer formed by the third GaN layer 66). This increases the channel potential, thereby increasing the on-resistance. In particular, the electrons trapped at the deep acceptor level in the crystal are not readily released. Therefore, the on-resistance may remain high. Such a deep acceptor level may be formed by, for example, doping the first nitride semiconductor layer 16 and/or the buffer layer 14 with impurities.

The first nitride semiconductor layer 16 is configured to maintain the density of crystal defects within a predetermined range in order to limit increases in the on-resistance by compensating for the acceptor, which causes the electron trap described above. Crystal defects resulting from crystal strain affect formation of a donor level. From this viewpoint, the density of crystal defects in the crystals of the first nitride semiconductor layer 16 and/or in the crystal of the buffer layer 14 is controlled to form a donor level that compensates for the acceptor.

The density of crystal defects is typically evaluated using an X-ray rocking curve (XRC) measurement. The half width of an XRC is used as an index value that quantifies crystal strain and thus has a correlation with the density of crystal defects. More precisely, the half width is a full width at half maximum (FWHM) but is simply referred to as the half width.

In some embodiments, the density of crystal defects in the first nitride semiconductor layer 16 is controlled so that the XRC half width for a (102) surface of the first nitride semiconductor layer 16 is 1100 arcseconds or greater and 1400 arcseconds or less. To simplify the description, “the XRC half width for the (102) surface” of the first nitride semiconductor layer 16 may be simply referred to as the “(102) half width.” When the (102) half width is maintained within the range, the donor level resulting from the crystal defect compensates for the acceptor. This limits increases in the on-resistance. The relationship between the (102) half width and the on-resistance variation rate will be described later.

FIG. 3 is a schematic diagram illustrating the (102) surface of the first nitride semiconductor layer 16. The (102) surface of the first nitride semiconductor layer 16 is a crystal surface of a Miller index (102) in a hexagonal crystal, that is, the unit lattice of GaN forming the first nitride semiconductor layer 16. The (102) surface corresponds to a crystal surface M102 of a hexagonal HC illustrated in FIG. 3. The X-ray rocking curve for the (102) surface is referred to as a rocking curve obtained by performing X-ray diffraction on the (102) surface.

Types of crystal defect (dislocation) include an edge dislocation and a screw dislocation as lattice misalignment formed in the stacking direction of the crystal stack structure. A screw dislocation is inclined with respect to a direction perpendicular to a stacking surface of the crystal stack structure. Specifically, a screw dislocation is formed by tilting the crystal axis of the crystal growth orientation. An edge dislocation is formed in a direction perpendicular to the stacking surface of the crystal stack structure. Specifically, an edge dislocation is formed by twisting the crystal axis in the surface.

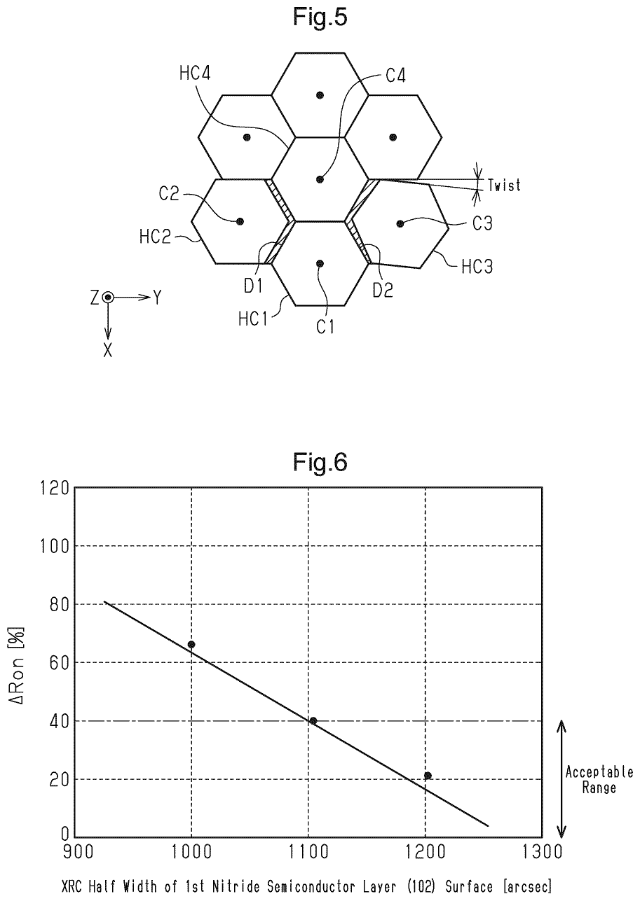

FIG. 4 is a schematic diagram illustrating a screw dislocation. FIG. 5 is a schematic diagram illustrating an edge dislocation. FIGS. 4 and 5 illustrate a single layer in a hexagonal crystal system having a crystal stack structure in the X-axis direction. FIG. 4 is a front view illustrating a portion of the crystal structure. FIG. 5 is a plan view of the crystal structure illustrated in FIG. 4.

As illustrated in FIG. 4, the screw dislocation is formed by a tilt of the c-axis C2 of the hexagonal crystal HC2 with respect to the c-axis C1 of the hexagonal crystal HC1 (and the c-axis C4 of the hexagonal crystal HC4 illustrated in FIG. 5). As illustrated in FIG. 5, the tilt of the c-axis C2 results in formation of a lattice misalignment D1, which is inclined with respect to a direction (Z-axis direction) perpendicular to the stacking surface of the crystal stack structure between the hexagonal crystal HC2 and the hexagonal crystals HC1 and HC4. The lattice misalignment D1 is taken on in the thickness-wise direction (X-axis direction) of the first nitride semiconductor layer 16. This forms a crystal defect (threading dislocation) resulting from the screw dislocation.

As illustrated in FIG. 5, the edge dislocation is formed by a twist about the c-axis C3 of the hexagonal crystal HC3. The twist about the c-axis C3 forms a lattice misalignment D2, which extends in a direction (Z-axis direction) orthogonal to the stacking surface of the crystal stack structure between the hexagonal crystal HC3 and the hexagonal crystals HC1 and HC4. The lattice misalignment D2 is taken on in the thickness direction (X-axis direction) of the first nitride semiconductor layer 16. This forms a crystal defect (threading dislocation) resulting from the edge dislocation.

The XRC half width for the (102) surface of the first nitride semiconductor layer 16 is an index value that reflects both of the lattice misalignments D1 and D2, more specifically, the crystal defect resulting from the screw dislocation and the crystal defect resulting from the edge dislocation.

FIG. 6 is a graph illustrating a relationship between the on-resistance variation rate ΔRon and the XRC half width for the (102) surface of the first nitride semiconductor layer 16 measured for various nitride semiconductor devices 10 including a first nitride semiconductor layer 16 having a different crystal defect density. The on-resistance variation rate ΔRon is obtained by measuring the on-resistance of a nitride semiconductor device 10 before and after a high-temperature reverse bias (HTRB) test is performed on the nitride semiconductor device 10. In the HTRB test, a stress voltage (e.g., 80% of rated voltage (e.g., 150V)) is applied to the drain electrode 26 of the HEMT, which is in an off-state, for a predetermined time (e.g., 60 hours or longer) at a high temperature (e.g., approximately 150° C.).

As illustrated in FIG. 6, the on-resistance variation rate ΔRon changes in accordance with the XRC half width for the (102) surface of the first nitride semiconductor layer 16. As the (102) half width increases, that is, as the crystal defect density of the first nitride semiconductor layer 16 increases, the on-resistance variation rate ΔRon decreases. In some embodiments, an acceptable range of the on-resistance variation rate ΔRon is set to 40% or less. In FIG. 6, the (102) half width satisfying the acceptable range is 1100 arcseconds or greater and 1250 arcseconds or less.

Although not illustrated in FIG. 6, even when the (102) half width is 1250 arcseconds or greater, the on-resistance variation rate ΔRon decreases as the (102) half width increases. However, when a large number of crystal defects is introduced, and a donor level is excessively formed in the crystals of the first nitride semiconductor layer 16 or the buffer layer 14, current may leak through the crystal defects (threading dislocation). This may result in a decrease the breakdown voltage of the first nitride semiconductor layer 16. Taking this point into consideration, the (102) half width is set to be 1100 arcseconds or greater and 1400 arcseconds or less.

### 6. Operation of Nitride Semiconductor Device

When drain voltage is applied to the drain electrode 26 of the nitride semiconductor device 10, which is configured as a HEMT, electrons are trapped in the acceptor level present in the crystal of the first nitride semiconductor layer 16 or the buffer layer 14. The electron trap causes the on-resistance to increase. In this regard, the first nitride semiconductor layer 16 is configured to have a crystal defect density that is sufficient to obtain a donor level compensating for the acceptor. More specifically, the crystal defect density of the first nitride semiconductor layer 16 is controlled so that the (102) half width of the first nitride semiconductor layer 16, which is used as an index representing the crystal defect density, is 1100 arcseconds or greater and 1400 arcseconds or less.

The first nitride semiconductor layer 16 may include a GaN composite layer in which one or more non-doped GaN layers and one or more impurity-doped GaN layers are alternately stacked. In such a GaN composite layer, the number of non-doped GaN layers and the thickness of each non-doped GaN layer and/or the number of impurity-doped GaN layers and the thickness of each impurity-doped GaN layer are adjusted to control the crystal defect density of the first nitride semiconductor layer 16.

In the example illustrated in FIG. 2, the first nitride semiconductor layer 16 includes a GaN composite layer in which a first GaN layer 62 (non-doped GaN layer), a second GaN layer 64 (impurity-doped GaN layer), and a third GaN layer 66 (non-doped GaN layer) are stacked. The first GaN layer 62 has a thickness of, for example, 50 nm or greater and 300 nm or less. The second GaN layer 64 has a thickness of, for example, 300 nm or greater and 600 nm or less. The third GaN layer 66 is, for example, 200 nm or greater and 500 nm or less.

The buffer layer 14 may additionally or alternatively include an AlGaN composite layer in which multiple AlGaN layers are stacked. In such an AlGaN composite layer, the number of AlGaN layers and the thickness of each AlGaN layer and/or the ratio of Al composition in the AlGaN layer may be adjusted to control the crystal defect density of the buffer layer 14. Thus, the crystal defect density of the first nitride semiconductor layer 16 formed on the buffer layer 14 is controlled.

In the example illustrated in FIG. 2, the buffer layer 14 includes the first buffer layer 52, which is formed of an AlN layer, and the second buffer layer 54, which is formed of the AlGaN composite layer in which the first to third AlGaN layers 54A, 54B, and 54C are stacked. The first to third AlGaN layers 54A, 54B, and 54C each have a thickness of, for example, 100 nm or greater and 300 nm or less. In this case, the thickness of the third AlGaN layer 54C may be, for example, two times or more than the thickness of the second AlGaN layer 54B, and may be, for example, 200 nm or greater. The proportions of Al composition in the first to third AlGaN layers 54A, 54B, and 54C are approximately 80% (±5%), approximately 50% (±5%), and approximately 20% (±5%).

In the example illustrated in FIG. 2, in the second buffer layer 54 (AlGaN composite layer), the third AlGaN layer 54C has a lower Al composition and a greater thickness than the second AlGaN layer 54B. This promotes occurrence of lattice relief (dislocation) in the third AlGaN layer 54C. As a result, the density of crystal defects is increased by the lattice relief. Thus, the crystal defect density of the first nitride semiconductor layer 16 formed on the buffer layer 14 is increased. As described above, when the crystal defect density of the buffer layer 14 is controlled, the crystal defect density of the first nitride semiconductor layer 16 is controlled.

The nitride semiconductor device 10 of the embodiment has the following advantages.

(1) The nitride semiconductor device 10 is configured so that the XRC half width for the (102) surface of the first nitride semiconductor layer 16 is 1100 arcseconds or greater and 1400 arcseconds or less. With this configuration, the first nitride semiconductor layer 16 maintains a crystal defect density that is sufficient to obtain a donor level compensating for the acceptor, which causes an electron trap. This limits decreases in the carrier (electron) concentration of the 2DEG 20 generated in the first nitride semiconductor layer 16, thereby limiting increases in the on-resistance.

(2) The XRC half width for the (102) surface of the first nitride semiconductor layer 16 is used as an index of the crystal defect density reflecting the crystal defect resulting from an edge dislocation and the crystal defect resulting from a screw dislocation. This allows for accurate control of the crystal defect density of the first nitride semiconductor layer 16.

(3) The first nitride semiconductor layer 16 includes the GaN composite layer in which the first to third GaN layers 62, 64, 66 are stacked. Each of the first and third GaN layers 62 and 66 is a non-doped GaN layer. The second GaN layer 64 is an impurity-doped GaN layer that is doped with carbon (C) as an impurity. In this structure, the thickness of each of the first to third GaN layers 62, 64, 66 may be adjusted to control the crystal defect density of the first nitride semiconductor layer 16. The first nitride semiconductor layer 16 includes an impurity-doped GaN layer (second GaN layer 64). This limits current leakage in the first nitride semiconductor layer 16, thereby improving the breakdown voltage.

(4) The buffer layer 14 includes the AlGaN composite layer (second buffer layer 14) in which the first to third AlGaN layers 54A, 54B, and 54C are stacked. The third AlGaN layer 54C is located in the uppermost layer of the AlGaN composite layer and has a lower Al composition and a greater thickness than the second AlGaN layer 54B located immediately under the third AlGaN layer 54C. For example, in this structure, the thickness of each of the first to third AlGaN layers 54A, 54B, and 54C and/or the ratio of Al composition may be adjusted to control the crystal defect density of the buffer layer 14. Thus, the crystal defect density of the first nitride semiconductor layer 16 formed on the buffer layer 14 is controlled.

(5) In the buffer layer 14, at least one of the first to third AlGaN layers 54A, 54B, and 54C is an impurity-doped AlGaN layer doped with at least one of carbon (C) and iron (Fe) as an impurity. In this structure, the buffer layer 14 includes an impurity-doped AlGaN layer. This limits current leakage in the buffer layer 14, thereby improving the breakdown voltage.

(6) In the nitride semiconductor device 10, the gate structure 22 includes the gate layer 30, which is formed on the second nitride semiconductor layer 18, and the gate electrode 32, which is formed on the gate layer 30. The gate layer 30 is formed of a GaN layer including an acceptor impurity, that is, a p-type GaN layer. When the gate layer 30 is arranged as described above, the nitride semiconductor device 10 is configured as a normally-off HEMT.

### Modified Examples

The above embodiment may be modified as described below. The above-described embodiment and the modified examples described below can be combined as long as the combined modifications remain technically consistent with each other.

The nitride semiconductor device 10 is not limited to the structure of the embodiment described with reference to FIG. 1. For example, the nitride semiconductor device 10 of the above embodiment is a normally-off HEMT. However, the present disclosure is not limited to a normally-off HEMT and may be applied to a normally-on HEMT. For example, the gate layer 30 may be omitted from the nitride semiconductor device 10 (or the gate layer 30 is formed as a nitride semiconductor layer that does not contain acceptor impurities) so that the nitride semiconductor device 10 becomes a normally-on HEMT.

The first nitride semiconductor layer 16 is not limited to the structure of the embodiment described with reference to FIG. 2. The first nitride semiconductor layer 16 does not necessarily have to include a GaN composite layer as long as GaN is included in a layer. The number of layers in the GaN composite layer and the structure of the GaN composite layer are not particularly limited. For example, the first nitride semiconductor layer 16 may include another nitride semiconductor layer (e.g., AlN layer) in addition to a GaN layer. The crystal defect density of the first nitride semiconductor layer 16 may be adjusted by another layer structure.

The buffer layer 14 is not limited to the structure of the embodiment described with reference to FIG. 2 and may include another nitride semiconductor layer. The number of layers in the AlGaN composite layer and the structure of the AlGaN composite layer are not particularly limited.

The gate layer 30 is not limited to the structure including the source-side extension 36 and the drain-side extension 38 and may include only the gate layer main body 34. The structure and shape of the source electrode 24 and the drain electrode 26 are not limited to those illustrated in FIG. 1.

In the present disclosure, the term “on” includes the meaning of “above” in addition to the meaning of “on” unless otherwise clearly indicated in the context. Therefore, for example, the phrase “first component formed on second component” is intended to mean that the first component may be formed on the second component in contact with the second component in one embodiment and that the first component may be located above the second component without contacting the second component in another embodiment. In other words, the term “on” does not exclude a structure in which another component is formed between the first component and the second component.

The Z-axis direction as referred to in the present disclosure does not necessarily have to be the vertical direction and does not necessarily have to fully conform to the vertical direction. Accordingly, in the structures of the present disclosure, “up” and “down” in the Z-axis direction as referred to in this specification are not limited to “up” and “down” in the vertical direction. For example, the X-axis direction may conform to the vertical direction. The Y-axis direction may conform to the vertical direction.

The phrases “first” and “second” and the like in this disclosure are used to clearly distinguish one from another and do not necessarily have to include the components of order.

### CLAUSES

Technical concepts that can be understood from each of the above embodiments and modified examples will now be described. The reference signs of the components in the embodiments are given to the corresponding components in clauses with parentheses. The reference signs are used as examples to facilitate understanding, and the components in each clause are not limited to those components given with the reference signs.

[Clause A1] A nitride semiconductor device (10), including:
a first nitride semiconductor layer (16);
a second nitride semiconductor layer (18) formed on the first nitride semiconductor layer (16) and having a band gap that is larger than that of the first nitride semiconductor layer (16); and
a gate electrode (32), a source electrode (24), and a drain electrode (26) formed above the second nitride semiconductor layer (18), where
the first nitride semiconductor layer (16) is a layer including GaN, and
an X-ray rocking curve for a (102) surface of the first nitride semiconductor layer (16) has a half width that is 1100 arcseconds or greater and 1400 arcseconds or less.

[Clause A2] The nitride semiconductor device (10) according to clause A1, where
the first nitride semiconductor layer (16) includes a GaN composition layer in which multiple GaN layers (62, 64, 66) are stacked,
the multiple GaN layers (62, 64, 66) in the GaN composition layer include an impurity-doped GaN layer (64) and a non-doped GaN layer (62; 66) that are alternately stacked, the impurity-doped GaN layer (64) is doped with an impurity forming an acceptor level,
the GaN composition layer includes an uppermost layer formed of the non-doped GaN layer (66), and
the second nitride semiconductor layer (18) is formed on the non-doped GaN layer (66) located at the uppermost layer in the GaN composition layer.

[Clause A3] The nitride semiconductor device (10) according to clause A2, further including:
a semiconductor substrate (12); and
a buffer layer (14) formed on the semiconductor substrate (12), where
the GaN composition layer has a three-layer structure including a first GaN layer (62) located on the buffer layer (14), a second GaN layer (64) located on the first GaN layer (62), and a third GaN layer (66) located on the second GaN layer (64),
the first GaN layer (62) and the third GaN layer (66) are each formed of the non-doped GaN layer,
the second GaN layer (64) is formed of the impurity-doped GaN layer, and
the second nitride semiconductor layer (18) is formed on the third GaN layer (66).

[Clause A4] The nitride semiconductor device (10) according to clause A3, where the first GaN layer (62) has a thickness of 50 nm or greater and 300 nm or less.

[Clause A5] The nitride semiconductor device (10) according to any one of clauses A2 to A4, where the impurity in the impurity-doped GaN layer (64) is carbon (C).

[Clause A6] The nitride semiconductor device (10) according to clause A1, further including:
a semiconductor substrate (12); and
a buffer layer (14) formed on the semiconductor substrate (12), where
the first nitride semiconductor layer (16) is formed on the buffer layer (14),
the buffer layer (14) includes an AlGaN composite layer (54) in which multiple AlGaN layers (54A, 54B, 54C) are stacked,
the multiple AlGaN layers (54A, 54B, 54C) include an uppermost AlGaN layer (54C) and a lower AlGaN layer (54B) located immediately under the uppermost AlGaN layer (54C), and
the uppermost AlGaN layer (54C) has an aluminum composition that is lower than that of the lower AlGaN layer (54B) and a thickness that is greater than that of the lower AlGaN layer (54B).

[Clause A7] The nitride semiconductor device (10) according to clause A6, further including:
at least one of the multiple AlGaN layers (54A, 54B, 54C) is an impurity-doped AlGaN layer (54A; 54B; 54C) doped with an impurity that forms an acceptor level.

[Clause A8] The nitride semiconductor device (10) according to clause A7, where the impurity in the impurity-doped AlGaN layer (54A; 54B; 54C) is at least one of carbon (C) and iron (Fe).

[Clause A9] The nitride semiconductor device (10) according to any one of clauses A6 to A8, where
the first nitride semiconductor layer (16) includes a GaN composition layer in which multiple GaN layers (62, 64, 66) are stacked,
the multiple GaN layers (62, 64, 66) include
   a first GaN layer (62) located on the AlGaN composite layer (54) and formed of a non-doped GaN layer,
   a second GaN layer (64) located on the first GaN layer (62) and formed of an impurity-doped GaN layer doped with an impurity that forms an acceptor level, and
   a third GaN layer (66) located on the second GaN layer (64) and formed of a non-doped GaN layer, and
the second nitride semiconductor layer (18) is formed on the third GaN layer (66).

[Clause A10] The nitride semiconductor device (10) according to any one of clauses A1 to A9, further including:
a third nitride semiconductor layer (30) formed on the second nitride semiconductor layer (18) and including an acceptor impurity,
where the gate electrode (32) is formed on the third nitride semiconductor layer (30).

[Clause B1] A nitride semiconductor device (10), including:
a semiconductor substrate (12);
a buffer layer (14) formed on the semiconductor substrate (12);
a first nitride semiconductor layer (16) formed on the buffer layer (14);
a second nitride semiconductor layer (18) formed on the first nitride semiconductor layer (16) and having a band gap that is larger than that of the first nitride semiconductor layer (16); and
a gate electrode (32), a source electrode (24), and a drain electrode (26) formed above the second nitride semiconductor layer (18), where
the buffer layer (14) includes an AlGaN composite layer (54) in which multiple AlGaN layers (54A, 54B, 54C) are stacked,
the first nitride semiconductor layer (16) includes a GaN composition layer in which multiple GaN layers (62, 64, 66) are stacked,
the multiple GaN layers (62, 64, 66) in the GaN composition layer include an impurity-doped GaN layer (64) and a non-doped GaN layer (62; 66) that are alternately stacked, the impurity-doped GaN layer (64) is doped with an impurity forming an acceptor level,
the GaN composition layer includes an uppermost layer formed of the non-doped GaN layer (66),
the second nitride semiconductor layer (18) is formed on the non-doped GaN layer (66) located at the uppermost layer in the GaN composition layer, and
the multiple AlGaN layers (54A, 54B, 54C) include an uppermost AlGaN layer (54C) and a lower AlGaN layer (54B) located immediately under the uppermost AlGaN layer (54C), the uppermost AlGaN layer (54C) has an aluminum composition that is lower than that of the lower AlGaN layer (54B) and a thickness that is greater than that of the lower AlGaN layer (54B).

[Clause B2] The nitride semiconductor device (10) according to clause B1, where
the GaN composition layer has a three-layer structure including a first GaN layer (62) located on the buffer layer (14), a second GaN layer (64) located on the first GaN layer (62), and a third GaN layer (66) located on the second GaN layer (64),
the first GaN layer (62) and the third GaN layer (66) are each formed of the non-doped GaN layer,
the second GaN layer (64) is formed of the impurity-doped GaN layer, and
the second nitride semiconductor layer (18) is formed on the third GaN layer (66).

[Clause B3] The nitride semiconductor device (10) according to clause B1 or B2, where at least one of the multiple AlGaN layers (54A, 54B, 54C) is an impurity-doped AlGaN layer (54A; 54B; 54C) doped with an impurity that forms an acceptor level.

Various changes in form and details may be made to the examples above without departing from the spirit and scope of the claims and their equivalents. The examples are for the sake of description only, and not for purposes of limitation. Descriptions of features in each example are to be considered as being applicable to similar features or aspects in other examples. Suitable results may be achieved if sequences are performed in a different order, and/or if components in a described system, architecture, device, or circuit are combined differently, and/or replaced or supplemented by other components or their equivalents. The scope of the disclosure is not defined by the detailed description, but by the claims and their equivalents. All variations within the scope of the claims and their equivalents are included in the disclosure.

What is claimed is:

1. A nitride semiconductor device, comprising:
a first nitride semiconductor layer;
a second nitride semiconductor layer formed on the first nitride semiconductor layer and having a band gap that is larger than that of the first nitride semiconductor layer; and
a gate electrode, a source electrode, and a drain electrode formed above the second nitride semiconductor layer, wherein
the first nitride semiconductor layer is a layer including GaN, and
an X-ray rocking curve for a surface of the first nitride semiconductor layer has a half width that is 1100 arcseconds or greater and 1400 arcseconds or less.

2. The nitride semiconductor device according to claim 1, wherein
the first nitride semiconductor layer includes a GaN composition layer in which multiple GaN layers are stacked,
the multiple GaN layers in the GaN composition layer include an impurity-doped GaN layer and a non-doped GaN layer that are alternately stacked, the impurity-doped GaN layer is doped with an impurity forming an acceptor level,
the GaN composition layer includes an uppermost layer formed of the non-doped GaN layer, and
the second nitride semiconductor layer is formed on the non-doped GaN layer located at the uppermost layer in the GaN composition layer.

3. The nitride semiconductor device according to claim 2, further comprising:
a semiconductor substrate; and
a buffer layer formed on the semiconductor substrate, wherein
the GaN composition layer has a three-layer structure including a first GaN layer located on the buffer layer, a second GaN layer located on the first GaN layer, and a third GaN layer located on the second GaN layer,
the first GaN layer and the third GaN layer are each formed of the non-doped GaN layer,
the second GaN layer is formed of the impurity-doped GaN layer, and
the second nitride semiconductor layer is formed on the third GaN layer.

4. The nitride semiconductor device according to claim 3, wherein the first GaN layer has a thickness of 50 nm or greater and 300 nm or less.

5. The nitride semiconductor device according to claim 2, wherein the impurity in the impurity-doped GaN layer is carbon.

6. The nitride semiconductor device according to claim 1, further comprising:
a semiconductor substrate; and
a buffer layer formed on the semiconductor substrate, wherein
the first nitride semiconductor layer is formed on the buffer layer,
the buffer layer includes an AlGaN composite layer in which multiple AlGaN layers are stacked,
the multiple AlGaN layers include an uppermost AlGaN layer and a lower AlGaN layer located immediately under the uppermost AlGaN layer, and
the uppermost AlGaN layer has an aluminum composition that is lower than that of the lower AlGaN layer and a thickness that is greater than that of the lower AlGaN layer.

7. The nitride semiconductor device according to claim 6, further comprising:
at least one of the multiple AlGaN layers is an impurity-doped AlGaN layer doped with an impurity that forms an acceptor level.

8. The nitride semiconductor device according to claim 7, wherein the impurity in the impurity-doped AlGaN layer is at least one of carbon and iron.

9. The nitride semiconductor device according to claim 6, wherein
the first nitride semiconductor layer includes a GaN composition layer in which multiple GaN layers are stacked,
the multiple GaN layers include
a first GaN layer located on the AlGaN composite layer and formed of a non-doped GaN layer,
a second GaN layer located on the first GaN layer and formed of an impurity-doped GaN layer doped with an impurity that forms an acceptor level, and
a third GaN layer located on the second GaN layer and formed of a non-doped GaN layer, and
the second nitride semiconductor layer is formed on the third GaN layer.

10. The nitride semiconductor device according to claim 1, further comprising:
a third nitride semiconductor layer formed on the second nitride semiconductor layer and including an acceptor impurity,
wherein the gate electrode is formed on the third nitride semiconductor layer.
